(19) United States
(12) Patent Application Publication
(10) Pub. No.: US 2019/0180654 A1
(43) Pub. Date: Jun. 13, 2019

(54) MODULE FOR A VIDEO WALL HAVING A FILM

(71) Applicant: OSRAM Opto Semiconductors GmbH, Regensburg (DE)

(72) Inventors: Jürgen MOOSBURGER, Lappersdorf (DE); Frank SINGER, Regenstauf (DE); Thomas SCHWARZ, Regensburg (DE); Alexander MARTIN, Sinzing (DE)

(21) Appl. No.: 16/301,012

(22) PCT Filed: May 11, 2017
(86) PCT No.: PCT/EP2017/061357

§ 371 Date: Nov. 13, 2018

(30) Foreign Application Priority Data
May 17, 2016 (DE) 10 2016 109 040.9

(51) Int. Cl. G09F 9/302; G02B 3/00; G09F 9/33; H01L 25/075; H01L 33/58

(52) U.S. Cl. CPC G09F 9/3026; G02B 3/0056; H01L 33/58; H01L 25/0753; G09F 9/33

(57) ABSTRACT

A module for a video wall has at least one device including at least one light-emitting component arranged on a carrier, a film is arranged on the device, the film includes an optical element, the optical element is configured to influence light irradiation onto the devices and/or light emission of the devices, the devices are arranged in a grid, interspaces in the form of a lattice structure are provided between the devices, the film includes a covering structure, the covering structure includes at least one part of the lattice structure of the interspaces, the covering structure is arranged above the interspaces and covers the interspaces from above, and the film is laminated thereon.

### TECHNICAL FIELD

This disclosure relates to a module for a video wall comprising a film.

### BACKGROUND

Video walls comprising a multiplicity of LED devices, wherein one LED device is provided for one pixel are known. The LED device comprises a housing and at least one or more, in particular three, LED chips. For better visibility of the LEDs or protection against incident sunlight, shading elements may be provided above the LED chips. Furthermore, the individual LED housings may comprise lenses to improve the emission properties of the LED chip.

There is nonetheless a need to provide an improved module for a video wall.

### SUMMARY

We provide a module for a video wall, wherein at least one device including at least one light-emitting component is arranged on a carrier, a film is arranged on the device, the film includes an optical element, the optical element is configured to influence light irradiation onto the devices and/or light emission of the devices, the devices are arranged in a grid, interspaces in the form of a lattice structure are provided between the devices, the film includes a covering structure, the covering structure includes at least one part of the lattice structure of the interspaces, the covering structure is arranged above the interspaces and covers the interspaces from above, and the film is laminated thereon.

We also provide a module for a video wall, wherein at least one device including at least one light-emitting component is arranged on a carrier, a film is arranged on the device, the film includes an optical element, the optical element is configured to influence light irradiation onto the devices and/or light emission of the devices, the devices are arranged in a grid, interspaces in the form of a lattice structure are provided between the devices, the film includes a covering structure, the covering structure includes at least one part of the lattice structure of the interspaces, and the covering structure is arranged above the interspaces and covers the interspaces from above.

### BRIEF DESCRIPTION OF THE DRAWINGS

FIG. 1 shows a schematic plan view of an excerpt from a video wall.

FIG. 2 shows a schematic partial cross section through the video wall.

FIG. 3 shows one example of a device comprising a plurality of light-emitting components.

FIG. 4 shows a partial cross section through the video wall comprising a film.

FIG. 5 shows a partial cross section through a video wall comprising a film, wherein a covering structure is formed in the film.

FIG. 6 shows a partial cross section through a further example of a video wall, wherein the optical element is formed in the form of a roughened film or a Fresnel structure.

FIG. 7 shows a partial cross section through one example of a video wall comprising a film comprising a roughened surface.

FIG. 8 shows a schematic illustration of a partial cross section through a further example of a video wall comprising a film comprising a Fresnel structure.

FIG. 9 shows a schematic partial cross section through a further example of a video wall comprising a film comprising shading elements.

FIG. 10 shows an enlarged illustration of a partial excerpt from the film comprising the shading elements from FIG. 9.

FIG. 11 shows a plan view of an enlarged partial excerpt from the video wall from FIG. 9.

FIG. 12 shows a plan view of a partial excerpt from a film comprising shading elements and comprising Fresnel structures.

FIG. 13 shows a schematic illustration of a partial excerpt from a film comprising shading elements and a Fresnel structure.

### LIST OF REFERENCE SIGNS

1 Video wall
2 Device
3 Trench
4 Mounting base
5 Module base
6 Circuit board
7 Electrical line
8 Electrical/electronic circuit
9 Optical element
10 Film
11 Adhesive layer
12 Lower functional layer
13 Carrier film
14 Upper functional layer
15 Covering structure
16 Roughened surface
17 Radiation-guiding element
18 Shading element
19 Recess
20 Shading material
26 Component
31 Light-emitting element

### DETAILED DESCRIPTION

One advantage of our module is that the optical properties of the module are improved. Moreover, the module comprises a small structural height. The advantage is achieved by virtue of the fact that a film is arranged on the devices, wherein the film comprises an optical element, and the optical element is configured to influence light irradiation onto the devices and/or light emission of the devices.

By applying a film, for example, with the aid of a single laminating process, it is possible to realize a multiplicity of functions. In particular, a laminating process is able to be carried out more simply than a potting process or a spraying process for a film.

The film may comprise a covering structure arranged above the lattice structure of the interspaces of the devices. The covering structure comprises a low reflectance for visible light. The low reflectance may be achieved, for example, by way of the choice of the material of the covering structure. In particular, the covering structure may be produced from a dark, in particular black, material such as plastic, for example. As a result, optically visible disturbing effects such as e.g. reflections by the interspaces are reduced for an observer. The film affords the possibility of arranging the covering structure very close above the interspaces and precisely above the lattice structure of the interspaces.

The film may comprise an adhesive layer and an upper functional layer. The optical element is formed in the upper functional layer. A secure connection between the film and the devices may be achieved with the aid of the adhesive layer.

A carrier film may be provided between the adhesive layer and the upper functional layer. The carrier film enables the film to be formed more stably. Moreover, providing the carrier film makes it possible for the upper functional layer to be controlled to the function of the optical element in terms of structure and in terms of chemical composition, without having to carry out carrier functions.

A lower functional layer may be formed between the adhesive layer and the carrier film. The lower functional layer may comprise, for example, the covering structure for the interspaces. It is thus possible to provide a film for which two functional layers are provided, wherein the two functional layers carry out different optical functions.

The carrier may comprise a circuit board comprising electrical lines and/or circuits, wherein the devices are arranged on the circuit board. The devices electrically conductively connect to the lines and the electrical circuits of the circuit board. As a result, it is possible to achieve simple and secure line routing without significantly influencing the optical properties of the video wall. The electrical lines are formed, for example, such that the devices are individually drivable.

The optical element may be formed as a radiation-guiding element for the electromagnetic radiation of the at least one device. In this way, it is possible to improve color rendering and image reproduction, for example, with regard to an emission space. In particular, the emission direction of the video wall may be delimited upward and downward. Moreover, the lateral emission of the video wall may be extended. In this way, the video wall may be viewed better from a larger field of view.

The optical element may be formed as a Fresnel structure. The optical element may be formed as a roughened surface. The roughened surface ensures that reflections at the video wall are reduced. The surface of the video wall thus appears matte. A higher contrast during image reproduction is achieved as a result.

The optical element may be formed as a shading element for at least one device. As a result, disturbing light irradiations, for example, as a result of the sun may be kept away from the devices. Consequently, color falsifications as a result of light irradiation are reduced, in particular avoided.

The shading element may be introduced in a recess of a structured film. Consequently, the shading element may be formed on the film in the form of a metal structure.

The shading element may be arranged at a predefined angle with respect to a plane of the component or else comprise predefined shapes for improved shading of the device.

The devices may comprise a lateral distance from one another which is less than 0.8 mm, in particular less than 0.3 mm. Particularly in such small distances, it may become difficult to fill the interspaces with a potting material. Consequently, covering the interspaces with the aid of the covering structure in the film offers a simpler and secure covering of the interspaces.

The above-described properties, features and advantages and the way in which they are achieved will become clearer and more clearly understood in association with the following description of examples explained in greater detail in association with the drawings.

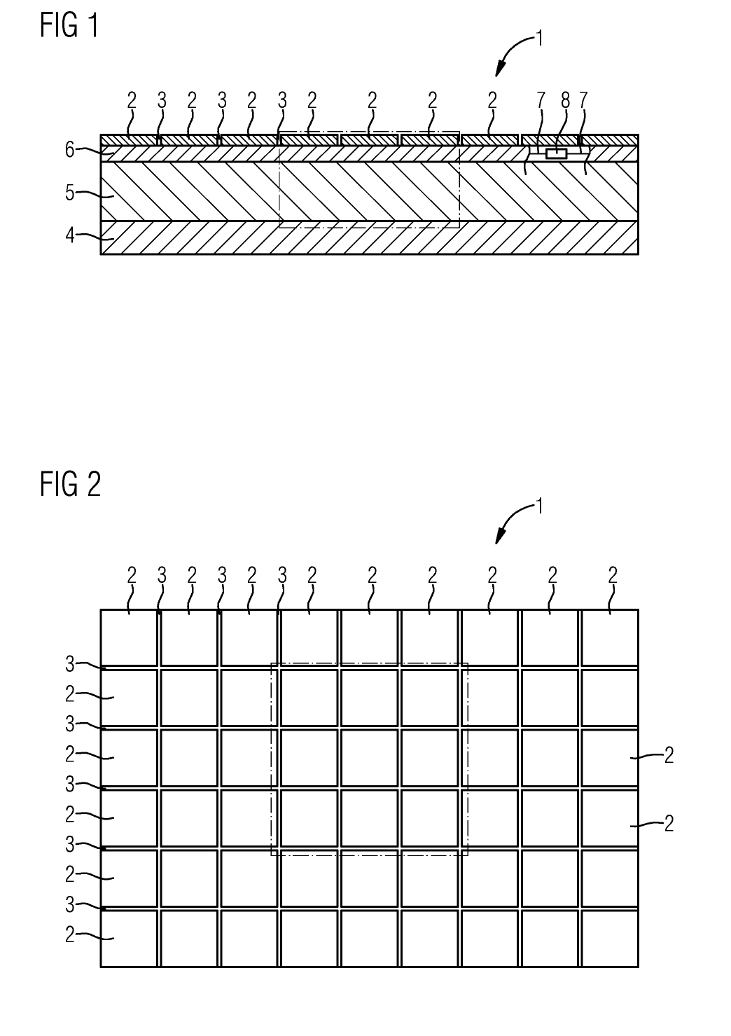

FIG. 1 shows, in a schematic plan view, a partial excerpt from a video wall 1 comprising a module comprising a plurality of devices 2. A video wall 1 may comprise one or more modules. In the example illustrated, the devices 2 are formed in square fashion and arranged in a uniform grid. Each device 2 comprises at least one light-emitting component. The light-emitting component may be formed e.g. as a light-emitting diode or as a laser diode. Between the components 2, trenches 3 are provided, which are filled, for example, with a filling material in particular with a dark in particular black, plastic. The term “light” is understood to mean any type of electromagnetic radiation, in particular visible light or infrared light.

FIG. 2 shows a schematic illustration of an enlarged partial cross section through the video wall 1 from FIG. 1. The module of the video wall 1 comprises a mounting base 4 on which a module base 5 is arranged. The mounting base 4 may comprise holding means to secure the video wall 1 e.g. to a building. The module base 5 may comprise mechanical securing elements and connectors to electrically connect the devices 2, in particular the light-emitting components. A circuit board 6 is arranged on the module base 5. The circuit board 6 may comprise electrical lines 7 and/or electrical circuits 8 to drive the devices 2. The devices 2 are secured on the circuit board 6. The devices 2 may be adhesively bonded, soldered or secured to the circuit board 6 by other means. The trenches 3 are formed between the devices 2. The trenches 3 may comprise a width of 1 mm or less, in particular a width of less than 0.8 mm, in particular less than 0.3 mm. The small distance between the devices 2 provides for a high device density and thus a high luminosity of the video wall. The circuit board 6, the module base 5 and the mounting base 4 constitute a carrier. The carrier may be formed only by the circuit board 6 and the mounting base 4 or the module base 5 may be dispensed with. Moreover, a circuit board 6 comprising no electrical lines 7 and/or no electrical circuits 8 may also be provided.

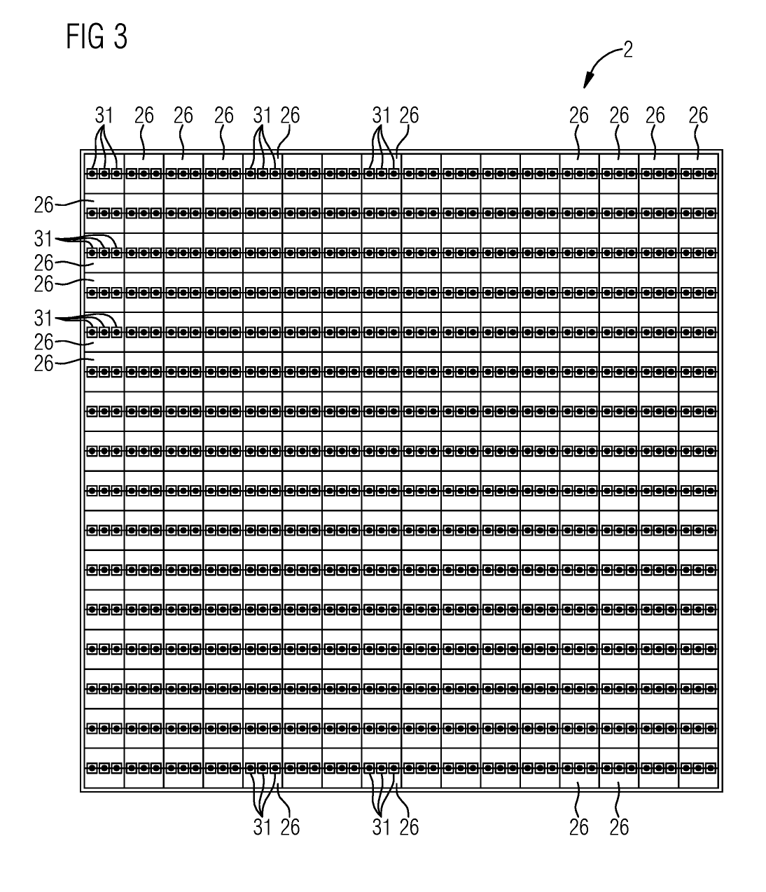

FIG. 3 shows a plan view of a device 2 in a schematic illustration. In the example illustrated, the device 2 comprises a multiplicity of components 26. The components 26 are formed in square fashion and arranged in a 16×16 grid. One component 26 constitutes one image pixel. A component 26 comprises three light-emitting elements 31 arranged in a row. The component 26 may also comprise more or fewer light-emitting elements 31. The light-emitting elements may be formed e.g. as light-emitting diodes or as laser diodes.

The device 2 constitutes a 16×16 multipixel LED housing. The device 2 comprises electrical lines and/or electrical circuits that make it possible for each image pixel, that is to say each component 26, to be driven individually. The device 2 may also comprise more or fewer components 26. By way of example, the device 2 may be formed in the form of a 4×4 multipixel LED housing or in the form of a 32×32 multipixel LED housing. In the smallest example, the device 2 comprises a single component 26 comprising a single light-emitting element 31.

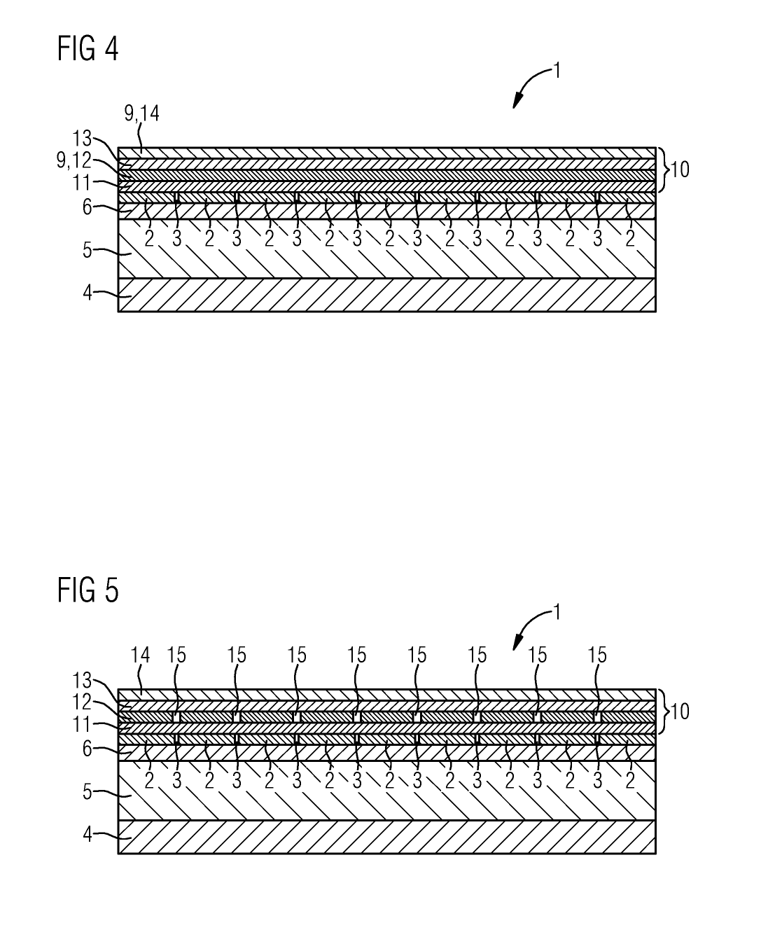

FIG. 4 shows a schematic partial cross section through a video wall constructed in accordance with FIG. 2, wherein a film 10 is applied on the video wall 1. The film 10 may be applied by adhesive bonding, laminating or by other methods. The film 10 comprises an adhesive layer 11 that adheres on the devices 2. A lower functional layer 12 is applied on the adhesive layer 11. A carrier film 13 is provided on the lower functional layer 12. An upper functional layer 14 is arranged on the carrier film 13. The lower functional layer 12 and/or the carrier film 13 may be dispensed with. The lower and upper functional layers 12, 14 and the carrier film 13 may be formed, for example, from plastic, silicone, epoxy material, glass or thermoplastics. The individual layers of the film 10 may be produced with the aid of photo patterning methods, printing methods, jet methods or embossing methods.

The film 10 is, for example, provided as a completed film and adhesively bonded onto the devices 2 with the aid of a laminating process. In this case, the film may be applied with the aid of a roll laminating process or a vacuum laminating process. Depending on the example of the video wall 1 and the film 10, it may be necessary to adjust the film 10 in relation to the structures and arrangements of the components 2 or the image pixels of the video wall. Both the lower functional layer 12 and the upper functional layer 14 may carry out optical functions. A module for a video wall comprises at least one device comprising at least one light-emitting component arranged on a carrier, wherein a film is arranged on the device, the film comprises an optical element 9, and the optical element 9 is configured to influence light irradiation onto the device and/or light emission of the device.

FIG. 5 shows a schematic partial cross section through a video wall 1 comprising a film 10, wherein a covering structure 15 is formed as optical element in the lower functional layer 12. The covering structure 15 optically covers interspaces, that is to say trenches 3, between the devices 2. To that end, the covering structure 15 is arranged above the trenches 3. The covering structure 15 may be formed from an optically black material. Moreover, the material of the lower functional layer 12 may be correspondingly colored with a black color to form the covering structure 15. Moreover, the covering structure 15 may be formed from a different material than the rest of the lower functional layer 12. By way of example, the covering structure 15 may be produced from a black plastic.

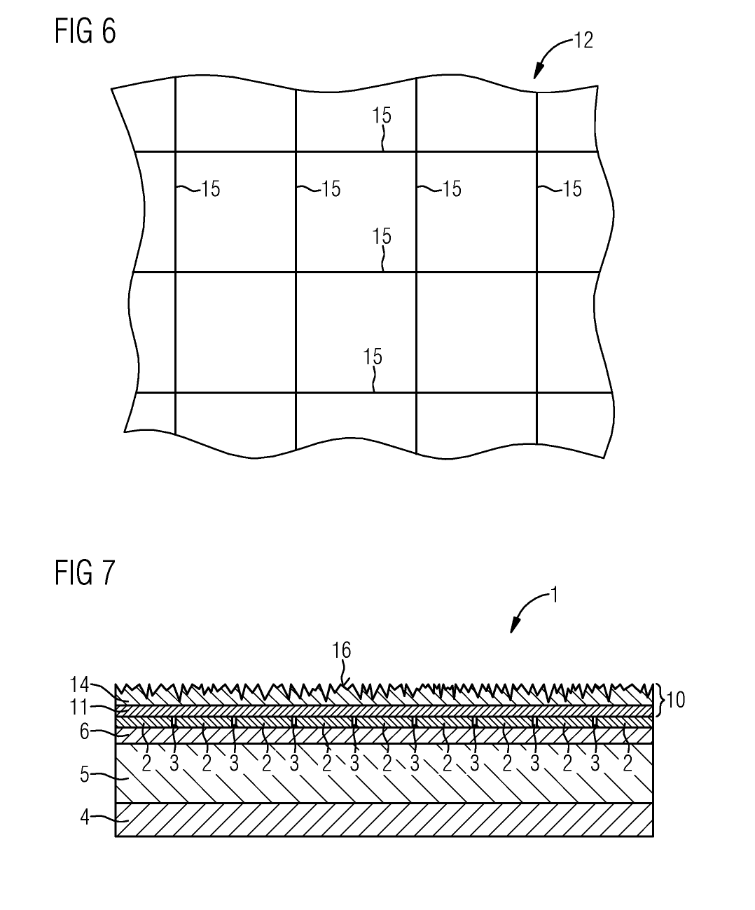

FIG. 6 shows a partial cross section through the lower functional layer 12, wherein the covering structure 15 is formed in a lattice-shaped fashion. This lattice shape corresponds to the lattice shape of the trenches 3 of the arrangement of devices 2, as evident with reference to FIG. 1. As a result of formation of the covering structure 15 in the lower functional layer 12, the distance between the covering structure 15 and the trenches 3 is very small, with the result that a good optical covering of the trenches 3 is achieved. A negative optical influencing of the image of the video wall by the trenches 3 is reduced, in particular prevented, with the aid of the covering structure 15. The carrier film 13 and the upper functional layer 14 may also be dispensed with in FIG. 4.

FIG. 7 shows a cross section through a further example of a video wall 1 comprising a film 10 in a schematic illustration, wherein only an upper functional layer 14 is provided in this example, the upper functional layer being connected to the devices 2 by the adhesive layer 11. The upper functional layer 14 is formed with a roughened surface 16. As a result, a matte surface is produced and specular reflections and reflections at the top side of the film 10 are avoided. The surface 16 may be roughened by chemical or mechanical methods. Moreover, the roughened surface 16 may be realized by a corresponding structure. However, the roughened surface 16 may also be produced, for example, with the aid of a photo patterning method, printing method or embossing method. The example of the film 10 in FIG. 7 may also be combined with the example in FIG. 5, wherein the covering structure 15 is formed in the lower functional layer 12. A carrier film 13 and a lower functional layer 12 are additionally provided in this case. The carrier film 13 may also be dispensed with in this example.

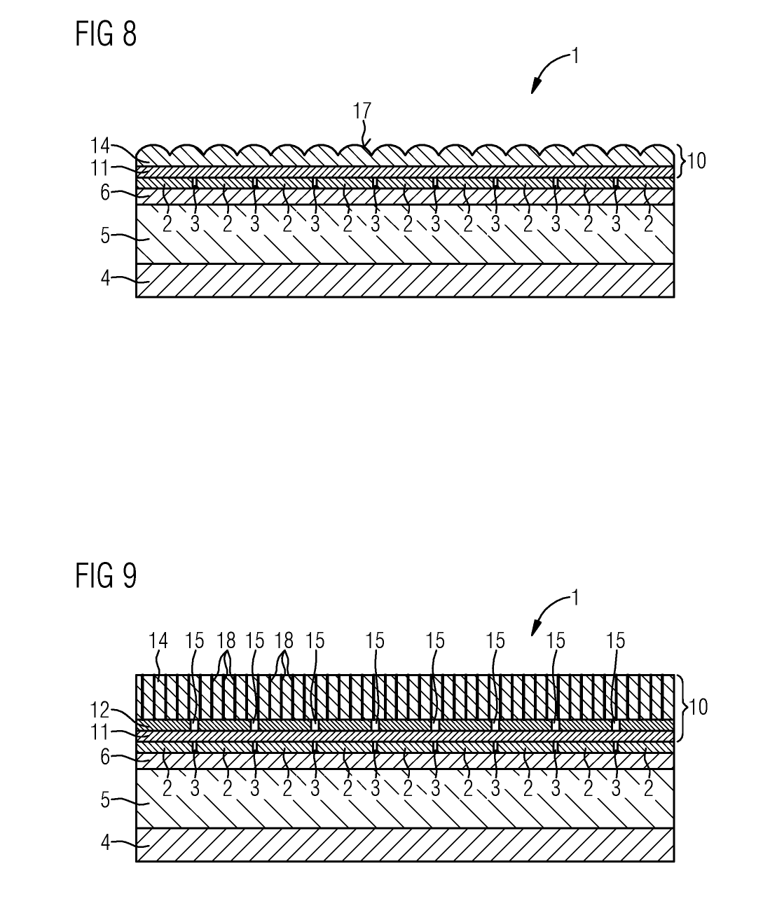

FIG. 8 shows a schematic illustration of a partial cross section through a further example of a video wall 1 comprising a film 10, wherein the upper functional layer 14 comprises a Fresnel structure 17. The upper functional layer 14 may connect to the devices 2 either by an adhesive layer 11, as illustrated. Moreover, a lower functional layer 12 and a carrier film 13, as illustrated in FIG. 5, may also be provided. The Fresnel structure 17 of the upper functional layer 14 provides for better light guiding in a predefined direction, in particular toward observers. The brightness and/or the contrast of the image information emitted by the video wall 1 are/is significantly improved as a result.

FIG. 9 shows a schematic partial cross section through a further example of a video wall 1 comprising a film 10, wherein the upper functional layer 14 comprises covering elements 18. The shading elements 18 form a shading structure for the devices 2, in particular the components 26. The upper functional layer 14 is applied directly on the lower functional layer 12 such that the carrier film 13 was dispensed with. A carrier film 13 may be provided. In addition, however, the lower functional layer 12 may also be dispensed with.

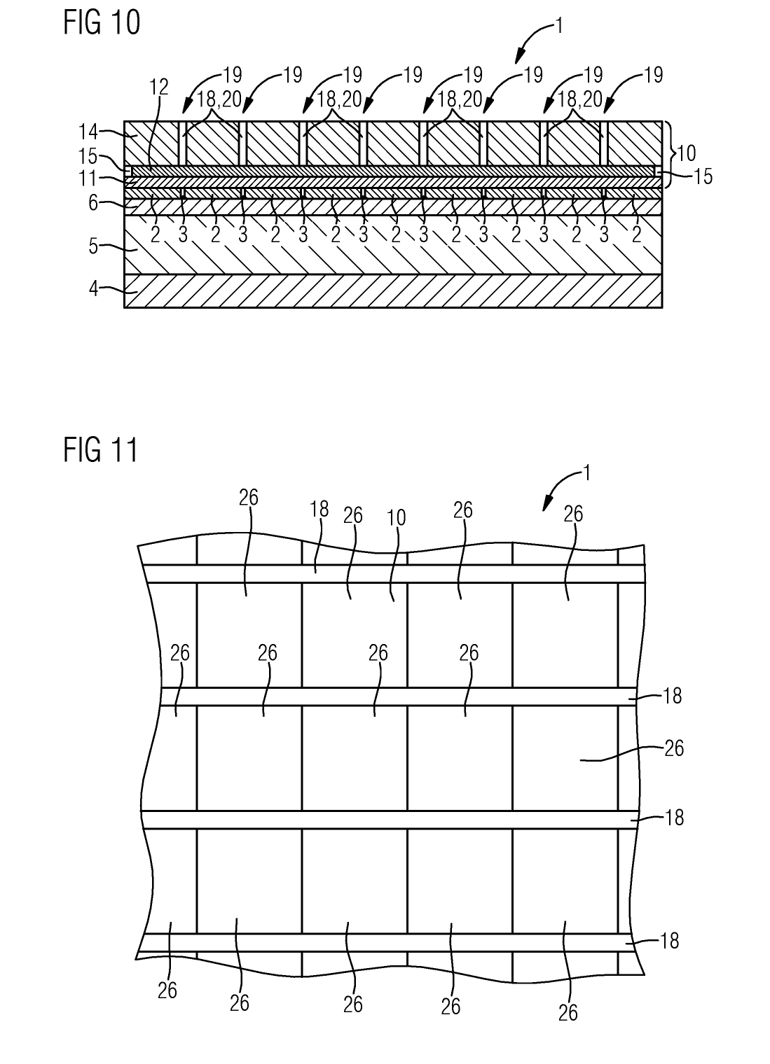

FIG. 10 shows an enlarged partial cross section through the arrangement from FIG. 9. The upper functional layer 14 comprises recesses 19, the recesses 19 being filled with a shading material 20, in particular metal. The shading material may be moreover dark, in particular black, plastic or colored transparent material, colored, for example, with black ink such as plastic, silicone, epoxy material or thermoplastics. Moreover, the shading material 20 may also be formed from a reflective material such as, for example, metal or dielectric material in the form of layer stacks. The shading material 20 may also be formed in the form of an absorbent material. The arrangement of the shading elements 18 is aligned in accordance with the arrangement of the devices 2 or the components 26 such that, for example, a row of devices 2 is shaded by a shading element 18. Consequently, a plurality of shading elements 18 arranged in parallel are provided for the shading of the video wall 1. To produce the shading elements 18, the upper functional layer 14 may be photopatterned by the recesses 19 being introduced into the upper functional layer 14. Afterward, the recesses 19 are filled with the shading material 20, in particular the metal.

FIG. 11 shows, in a schematic plan view of the video wall from FIG. 9, the arrangement of the shading elements 18 of the film 10 relative to the components 26. In this way, for each row of components 26 it is possible to achieve a shading from above, that is to say with respect to incident sunlight, with the aid of the shading elements 18. The shading elements 18 are formed e.g. as plate-shaped elements.

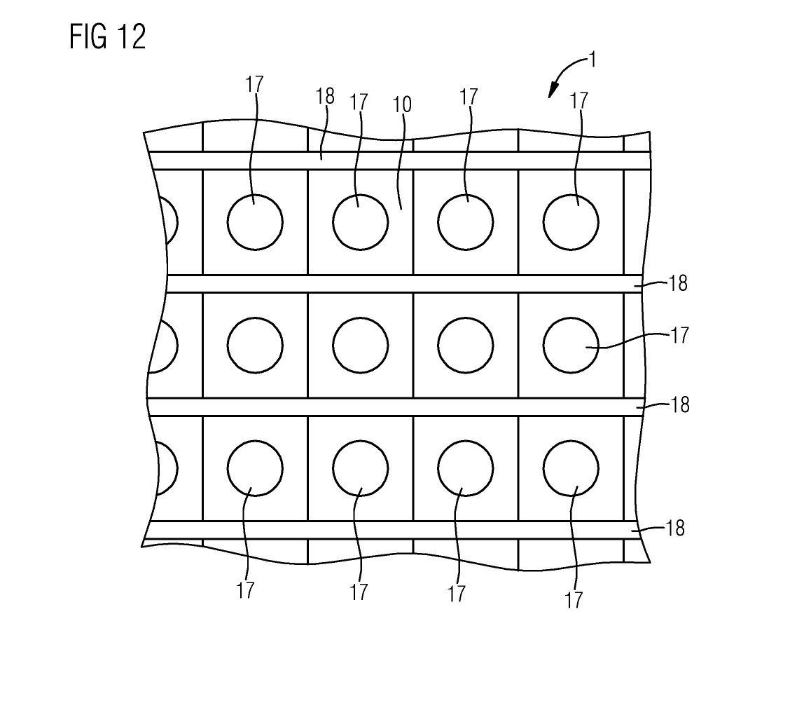

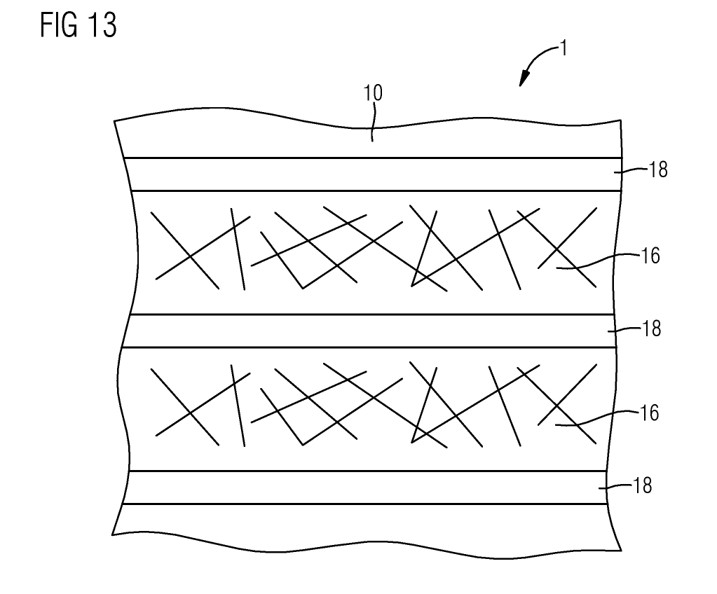

FIG. 12 shows, in a schematic plan view, a further example of a film 10 applied on a video wall 1. The film 10 comprises shading elements 18 and a radiation-guiding element 17 for the light of the components 26. Consequently, the function of the radiation-guiding elements 17 is combined with the shading function of the shading elements 18. The radiation-guiding elements may be formed e.g. in the form of Fresnel structures or in the form of lenses. The radiation-guiding elements 17 are aligned e.g. in each case with one device 2 or a group of devices 2. The lenses may be aligned centrally with components and/or devices.

FIG. 13 shows a further example of a video wall 1, a plan view of the film 10 being illustrated. The film 10 comprises shading elements 18 and a roughened surface 16. Consequently, the function of the shading elements 18 and the function of the roughened surface 16 may be combined.

Although our modules have been more specifically illustrated and described in detail by preferred examples, this disclosure is not restricted by the examples disclosed and other variations may be derived therefrom by those skilled in the art, without departing from the scope of protection of the appended claims.

This application claims priority of DE 10 2016 109 040.9, the subject matter of which is incorporated herein by reference.

1.-14. (canceled)

15. A module for a video wall, wherein at least one device comprising at least one light-emitting component is arranged on a carrier, a film is arranged on the device, the film comprises an optical element, the optical element is configured to influence light irradiation onto the devices and/or light emission of the devices, the devices are arranged in a grid, interspaces in the form of a lattice structure are provided between the devices, the film comprises a covering structure, the covering structure comprises at least one part of the lattice structure of the interspaces, the covering structure is arranged above the interspaces and covers the interspaces from above, and the film is laminated thereon.

16. The module according to claim 15, wherein the film comprises an adhesive layer and an upper functional layer, and the optical element is formed in the upper functional layer.

17. The module according to claim 16, wherein a carrier film is provided between the adhesive layer and the upper functional layer.

18. The module according to claim 16, wherein a carrier film is provided between the adhesive layer and the upper functional layer, a lower functional layer is formed between the adhesive layer and the carrier film, and the optical element is formed in the lower functional layer.

19. The module according to claim 15, wherein the carrier comprises a circuit board comprising electrical lines and/or electrical circuits, the devices are arranged on the circuit board, and the electrical lines are formed such that the devices are individually drivable.

20. The module according to claim 15, wherein the optical element is faulted as a radiation-guiding element for the electromagnetic radiation of at least one component.

21. The module according to claim 20, wherein the radiation-guiding element is formed as a Fresnel structure or as a lens.

22. The module according to claim 15, wherein the optical element is formed as a roughened surface.

23. The module according to claim 15, wherein the optical element comprises at least one shading element, the shading element is configured to reduce or prevent irradiation of light or sunlight onto the at least one component.

24. The module according to claim 23, wherein the shading element is introduced into a recess of a structured film.

25. The module according to claim 23, wherein the shading element is introduced into a recess of a structured film, and the shading element is formed in the form of a metal structure.

26. The module according to claim 15, wherein the device comprises an arrangement of a plurality of light-emitting components arranged in a grid, and a component comprises in particular three light-emitting elements.

27. A module for a video wall, wherein at least one device comprising at least one light-emitting component is arranged on a carrier, a film is arranged on the device, the film comprises an optical element, the optical element is configured to influence light irradiation onto the devices and/or light emission of the devices, the devices are arranged in a grid, interspaces in the form of a lattice structure are provided between the devices, the film comprises a covering structure, the covering structure comprises at least one part of the lattice structure of the interspaces, and the covering structure is arranged above the interspaces and covers the interspaces from above.

28. The module according to claim 27, wherein the covering structure comprises the lattice structure of the interspaces.

29. The module according to claim 27, wherein the covering structure is produced of black plastic.

30. The module according to claim 27, wherein a carrier film is provided between the adhesive layer and the upper functional layer, a lower functional layer is formed between the adhesive layer and the carrier film, the covering structure is formed in the lower functional layer, and the covering structure comprises the lattice structure of the interspaces.

31. The module according to claim 27, wherein a carrier film is provided between the adhesive layer and the upper functional layer, a lower functional layer is formed between the adhesive layer and the carrier film, the covering structure is formed in the lower functional layer, the covering structure comprises the lattice structure of the interspaces, and the covering structure is formed from a different material than the rest of the lower functional layer.
